(19) United States
(12) Patent Application Publication
(10) Pub. No.: US 2003/0180980 A1
(43) Pub. Date: Sep. 25, 2003

(54) Implantation for current confinement in nitride-based vertical optoelectronics

(76) Inventors: Tal Margalith, Santa Barbara, CA (US); Larry A. Coldren, Santa Barbara, CA (US); Shuji Nakamura, Santa Barbara, CA (US)

Correspondence Address: GREENBERG TRAURIG LLP, SUITE 400E, 2450 COLORADO AVENUE, SANTA MONICA, CA, 90404, US

(21) Appl. No.: 10/324,878

(22) Filed: Dec. 20, 2002

Related U.S. Application Data
(60) Provisional application No. 60/342,837, filed on Dec. 21, 2001.

(51) Int. Cl. H01L 21/00

(52) U.S. Cl. 438/48

(57) ABSTRACT

Ion implantation is used to increase the resistivity of semiconductor device layers for channeling the current through a low resistivity, unimplanted region such that carrier recombination takes place away from regions underneath the contacts. This eliminates absorption of light by the contact thereby providing higher light output power and better current-voltage characteristics to the semiconductor device. The incorporation of a regrown contact layer allows for an undamaged lateral conduction path, and the fabrication of ohmic contacts.

### BACKGROUND OF THE INVENTION

1. Field of the Invention

This invention pertains to the processing of semiconductor material in vertical opto-electronic devices.

More specifically, the invention pertains to applying a series of processing steps to nitride based materials (e.g., GaN, InN, AIN, BN based materials) for improving the quality of the cavity, and consequently, the opto-electronic device performance.

2. General Background and State of the Art

Recently, the demand for nitride based semiconductor materials (e.g., having Gallium Nitride or GaN) for opto-electronics has increased dramatically for applications such as video displays, optical storage, lighting, medical instruments, etc.. For many of these applications, vertical cavity structures (e.g., vertical cavity surface emitting lasers or VCSELs) offer advantages such as low-cost arrays and directional emission, in combination with a geometry that is easier to integrate into multi-device systems.

At present, there have only been a few reports of working Resonant Cavity Light Emitting Diodes or RCLEDs (e.g., Appl. Phys. Lett., 77, No. 12, (2000), 1744), and none on the successful fabrication of a current injection VCSEL. For these devices to work efficiently, the cavity losses must be kept to a minimum.

However, one of the factors that keep cavity losses high is the poor lateral conductivity of nitride based semiconductor structures (e.g., p-doped GaN) which leads to light generation in the active region directly below the p-contact. This results in significant light absorption, at the contacts, that is detrimental to the realization of

resonant cavity light emitting diodes (RCLEDs), VCSELs, and other vertical cavity devices.

A technique called ion implantation has been used in Gallium Arsenide (GaAs) and Indium Phosphide (InP) semiconductor systems to confine current through the selective disordering of device layers (e.g., IEEE J. Sel. Topics Quant. Elec., 4, No. 4, (1998), 595). While ion implantation has been explored in GaN, research has mainly focused on certain aspects of doping (e.g., Mat. Sci. and Engr., B59, (1999), 191), and for the purpose of disordering in primarily n-doped GaN (e.g., J. Appl. Phys., 78, No. 5, (1995), 3008).

Furthermore, one of the biggest hurdles in the path towards the fabrication of GaN-based devices is the difficulty associated with the p-doping. The conductivity of p-doped GaN is relatively low, mostly due to the large ionization energy of the magnesium dopant, and its compensation by the formation of Mg—H complexes. In 1989, researchers discovered that an activation step was necessary in order to achieve hole conduction in Mg-doped films. Others achieved hole concentrations of 3(10)¹⁷ cm⁻³ by using a thermal anneal in N₂. Yet even with an activation step, the hole mobility in GaN:Mg is only around 15 cm²/Vs for a carrier concentration around 5(10)¹⁷ cm⁻³. This is significantly lower, as compared with other III-V semicondictors, due to the deep acceptor energy inherent in wide bandgap compounds (see table below, which shows the P-doping statistics for III-V semiconductors at 300 degrees Kelvin).

| | E_{g} (eV) | Acceptor | μₕₒₗₑ (cm²/V-s) |
|---|---|---|---|
| InP | 1.35 | Zn (20 meV) | 150 |
| GaAs | 1.42 | Be (28 meV) | 400 |
| GaN | 3.36 | Mg (˜160 meV) | 10-15 |

Also, the possibility of increasing the lateral conductivity of p-GaN through the use of modulation-doped AlGaN/GaN superlattice (SL) structures, creating a 2D hole gas by taking advantage of the large polarization fields in GaN, has been researched. However, the gain in mobility (19 cm²/Vs, with a hole concentration of 1.9(10)¹⁸ cm⁻³) was minor and was accompanied by an increase in the threshold voltage of a laser diode where these superlattices were used. In fact, as shown in FIG. 1, the current-voltage (I-V) characteristics of LEDs employing these superlattice (SL) structures also demonstrate this increase.

The low lateral mobility would not necessarily be an issue in VCSEL fabrication if it were possible to conduct through a p-doped epitaxial mirror. However, the use of an epitaxial DBR necessitates the use of an intracavity contact. These contacts are usually ring-shaped for uniform current injection, relying on the fact that the conductivity is higher laterally than in the vertical direction. In p-GaN, where the lateral resistivity is very high, the use of these ring contacts by themselves is impossible. As seen in FIG. 2, the current would flow downward along the path of least resistance, such that radiative recombination would occur in the active region directly below the contact leading to reduced light power output from the device since the metal ring is in the cavity and readily absorbs the emitted light.

One solution, therefore, is to develop a scheme of uniform current spreading in a highly conductive layer. However, current spreading,.through the incorporation of thin transparent contacts, has its associated problems. Thin ohmic metal contacts are commonly used the in fabrication of LEDs, but are too absorbing even at their thinnest to be used in VCSELs. More recent efforts have involved the use of transparent, conductive oxides such as indium tin oxide (ITO) (e.g., Appl. Phys. Lett., 74. No. 26, (1999), 3930). The high conductivity and low absorption at around 400 nm make ITO an attractive choice for current spreading, but its robustness at high current densities is questionable, and as a p-contact it exhibits Schottky characteristics adding a voltage drop which can contribute to heating and consequently, reduced device performance.

Thus, what is needed is a method that can increase the resistivity of a nitride based semiconductor material (e.g., p-GaN) as well as the resisitivity of the underlying layers, selectively (e.g., in specific regions), in a manner to confine the current to a region of low resistivity. By confining the current to a region of low resistivity, the emission of light below the contacts is reduced thereby significantly improving the opto-electronic device performance (e.g., in terms of light output, current-voltage characteristics, etc.).

### INVENTION SUMMARY

The system according to the present invention includes a method for channeling the current through a low resistivity region such that carrier recombination takes place away from regions underneath the p-contact. This eliminates the absorption of light by the p-contact. Additionally, the optional incorporation of a regrown p-GaN contact layer allows an undamaged lateral conduction path and the fabrication of ohmic contacts.

Accordingly, in one aspect of the invention, the method includes ion implantation for increasing the resistivity of nitride based semiconductor material (e.g., p-doped GaN) and the underlying layers. This leads to channeling, or confining, of the current through a low resistivity and unimplanted region such that carrier recombination takes place away from regions underneath the p-contact.

In another aspect of the invention, the method for reducing the emission of light below a contact of a semiconductor structure includes selectively disordering a doped nitride based material (e.g., p-doped GaN) in a semiconductor structure, wherein the selective disordering substantially increases the resistance of the material, adjacent the p-contact, to a current thereby reducing the emission of light at the contact. By adding a region of substantially higher resistance, the structure permits the current to be confined to a region of substantially low resistance in the doped nitride based material. The selective disordering of the doped nitride based material is performed by ion implantation through a species of ions whose weight is larger than the weight of helium ions. As an example the species of ions could include aluminum ions. The nitride based material could include at least one of Ga, In, Al, or B.

In another aspect of the invention, the method ion implantation could be used for providing index wave-guiding of emitted light in a semiconductor structure. Specifically, the method includes selectively disordering a doped nitride based material in a semiconductor structure using ion implantation, wherein the ion implantation reduces the refractive index of the disordered and doped nitride based material thereby providing index wave-guiding of emitted light in the semiconductor structure. In essence, the disordered and doped nitride based material which has a lower refractive index surrounds the nitride based material having a higher refractive index. Thus, the index wave-guiding of emitted light is due to the lower refractive index material surrounding the higher refractive index material which leads to light guiding along the high refractive index material.

In another aspect of the invention, the ion implantation could be used for improving the light output in a vertical cavity surface emitting laser (VCSEL). Specifically, the method could include removing a portion of a substrate in the VCSEL using photo-electro-chemical (PEC) etching, depositing at least one mirror on the VCSEL, and selectively disordering a doped nitride based material in the VCSEL. The selective disordering substantially increases the resistance of the material, adjacent at least one contact of the VCSEL, to a current thereby improving the light output in the VCSEL.

In another aspect of the invention, the ion implantation could be used for improving the light output in a vertical cavity surface emitting laser (VCSEL). Specifically, the method could include growing a nitride based material on a substrate through lateral epitaxial overgrowth (LEO) process in the VCSEL, and selectively disordering a p-doped nitride based material in the VCSEL. The selective disordering substantially increases the resistance of the p-doped material, adjacent at least one contact of the VCSEL, to a current thereby improving the light output in the VCSEL.

In another aspect of the present invention, a semiconductor structure having reduced emission of light at a contact includes a selectively disordered and doped nitride based material, wherein the selectively disordered material has a substantially higher resistance, adjacent a contact, to a current thereby reducing the emission of light at the contact.

The above and other objects, features, and advantages of the present invention will become apparent from the following description read in conjunction with the accompanying drawings.

### BRIEF DESCRIPTION OF THE DRAWINGS

FIG. 1 shows the current-voltage (I-V) characteristics of LEDs employing p-superlattice (SL)structures of varying periods;

FIG. 2 is a cross-section schematic of a semiconductor device showing the current path and absorption for a ring p-contact;

FIG. 3 is a cross-section schematic of an implanted device, according to the present invention, showing the current and light paths and for a ring p-contact;

FIG. 4 is an exemplary TRIM data sheet (determined from SRIM 2000, a simulation program) displaying the stopping distances of aluminum ions in GaN;

FIG. 5 is an optical micrograph of confined emission in a device. The left photo shows the unbiased device, while the right photo clearly shows confinement within an aperture away from the contact. The metal ring has an inner diameter of 15 μm, while the unimplanted area in the center has a diameter of 5 μm;

FIG. 6 is a current-voltage (I-V) trace from a p-p TLM pattern, showing ohmic characteristics for contact pads on regrown p-doped material;

FIG. 7 shows a SRIM 2000 range profile for 180 keV of Al ions implanted into GaN;

FIG. 8 shows an current-voltage characteristics for LEDs implanted with 10¹² cm⁻² of Al ions at 180 keV, before and after RTA (activation) at 950 degrees Celsius for 3 mins.;

FIG. 9 is the p-p TLM current-voltage curves for a semiconductor structure implanted with 10¹² cm⁻² of Al ions at 180 keV, before and after RTA (reactivation) at 950 degrees Celsius for 3 mins.;

FIG. 10 is a process schematic for ion implantation and regrowth in a semiconductor device; and

FIG. 11 shows SIMS analysis of ion implanted samples for implantation with 10¹⁴ cm⁻² and 10¹⁵ cm⁻² of Al ions at 180 keV before and after regrowth.

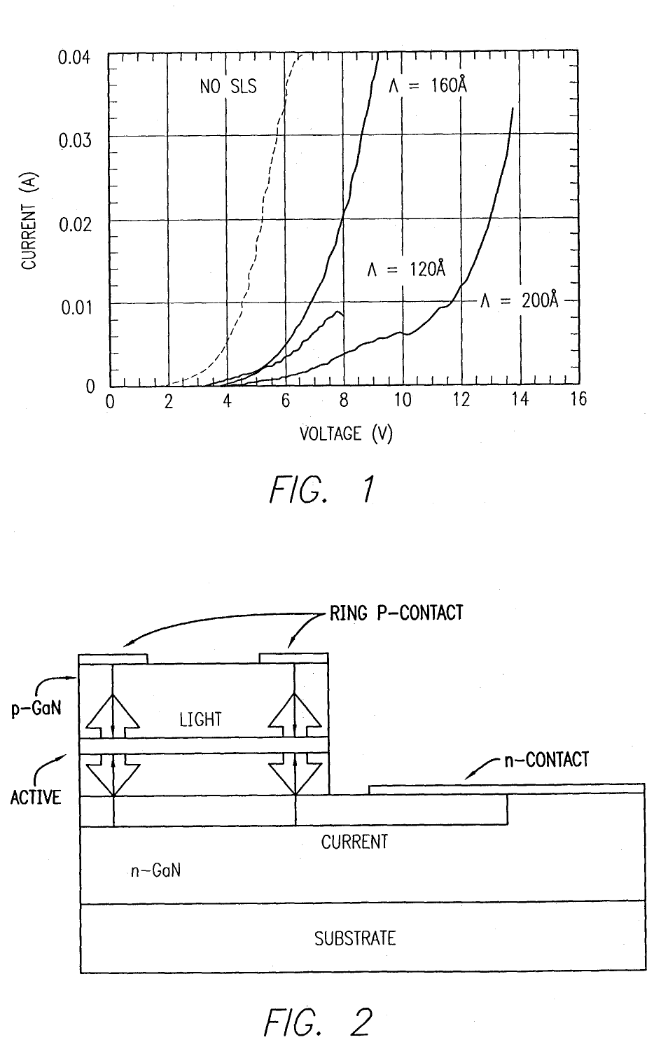

### DETAILED DESCRIPTION OF THE PREFERRED EMBODIMENTS

Ion Implantation:

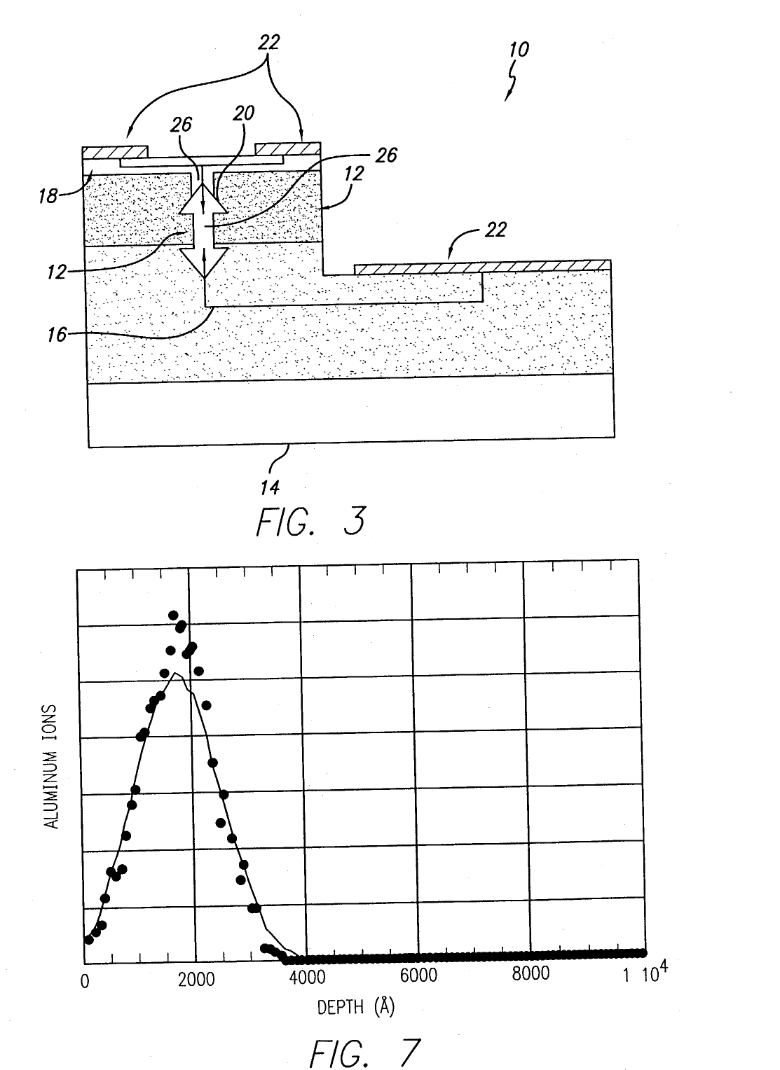

Referring now to the drawings and in particular to FIG. 3, therein shown is a semiconductor structure 10, according to the present invention, having a region of ionic implantation 12 for selectively disordering the region adjacent the contacts 22. Specifically, ion implantation 12 is used in a semiconductor device 10 to confine current 16 through the selective disordering of device layers 18. By selectively disordering the region adjacent the contacts 22, using ion implantation, the resistivity of this region is substantially increased thereby confining the current 16, away from the contacts 22 (depicted as ring p-doped), to the unimplanted region 26 having much lower resistance. By confining the current 16 to a region, away from the contacts 22, the emission of light 20 beneath the contacts 22 is avoided and thus light output from the device 10 is substantially increased. This significantly improves the semiconductor device performance in terms of light power output, current-voltage characteristics, etc.

In summary, ion implantation is used to force current to follow a specific path by creating region of high resistivity so that recombination of electrons and holes and subsequent photon, or light, emission occurs away from the metal contacts. Also, implantation can be used to create regions, in the semiconductor device layers, that are even more resistive than the original material thus forcing the current to flow through selective regions having lower resistance.

In one aspect of the invention, the semiconductor structure could be a VCSEL, RCLED, or other vertical opto-electronic devices having sapphire, GaN, AIN, SiC, or other suitable substrates 14 for Nitride growth, and the disordered region 18 could be a doped layer such as a p-doped GaN layer.

The choice of species used for ionic implantation 12 depends on subsequent processing. While lighter species such as hydrogen and helium can provide disordering, their implant profile may not hold if there is to be a subsequent annealing stage, (either through regrowth or activation). Heavier species can provide a more stable implant, but can cause increased damage to the overlying regions. In the present invention, aluminum ions have been used but any species of ions having weight larger than the weight of helium ions could be used.

Furthermore, the choice of the ions used for ion implantation 12 could enable the device 10 for index guiding of light. This is because of the low refractive index material (the material in the implanted region) surrounding a high refractive index material (the unimplanted material) leads to light guiding along the high refractive index material. For example, as more Al ions are used to implant GaN regions, the index of the implanted region is reduced, so as to have a low index AlGaN region surrounding a higher index GaN core.

Optimization:

The depth and profile of the ion implant species can be estimated by using SRIM2000 (Stopping Range of Ions in Matter), a simulation program that takes into account the density of the material being implanted and the energy and mass of the impacting species. The program is well known in the art and can be downloaded from http://www.research.ibm.com/ionbeams/SRIM/SRIMLEGL.HTM. However, SRIM does not take into account the crystal structure of the semiconductor. While not an issue in most semiconductors, significant channeling of the ion species can occur (as in wurtzitic GaN) due to the c-plane orientation of the material, consequently resulting in a smeared-out implant profile. This elongation is a concern when deciding on the position of the implant relative to the location of the active region 26. Placing the implant above the quantum wells can result in some lateral current spreading above the active region 26. Care should be taken to minimize losses incurred through recombination at the edge of the implant profile, where the carrier lifetime drops to zero, if the implant ions penetrate the active region 26.

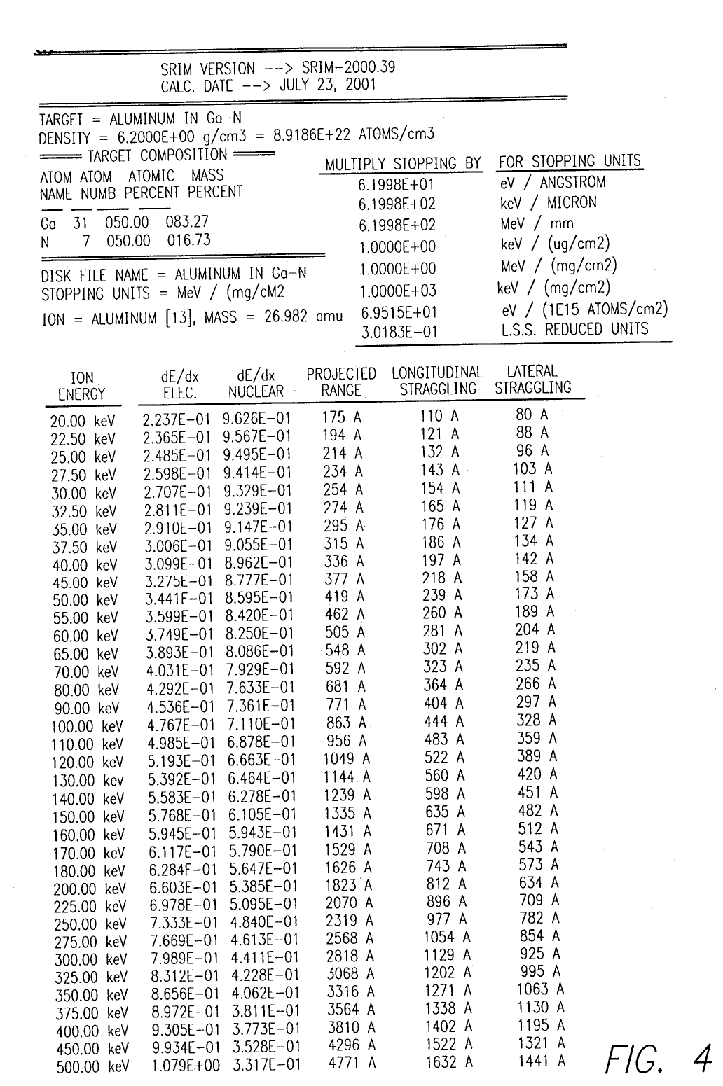

FIG. 4 is a data sheet obtained from SRIM2000 to determine the penetration depth of the ionic implant, when implanted at a given energy into a material of known density. The choice of energy is based on TRIM simulations, which takes into account the thickness of the region to be implanted (e.g., the p-GaN device layer), the depth desired, and the distribution of the implanted ions.

The parameter that substantially determines the conductivity of the implanted layer is the ion dosage. Standard LEDs were processed to ascertain the effect of different doses. Five quantum well structures were activated following the mesa definition. The semiconductor devices were then implanted with aluminum ions at 180 keV, with doses of 10¹², 10¹³, 10¹⁴, and 10¹⁵ cm⁻². The energy of 180 keV was selected so that the active region would be untouched. SRIM simulations sheet (FIG. 4) indicate that the stopping distance of 180 keV Al in GaN is approximately 1600 Å, with a straggle of 740 Å. The SRIM range profile for 180 keV Al ions implanted into GaN is shown in FIG. 7.

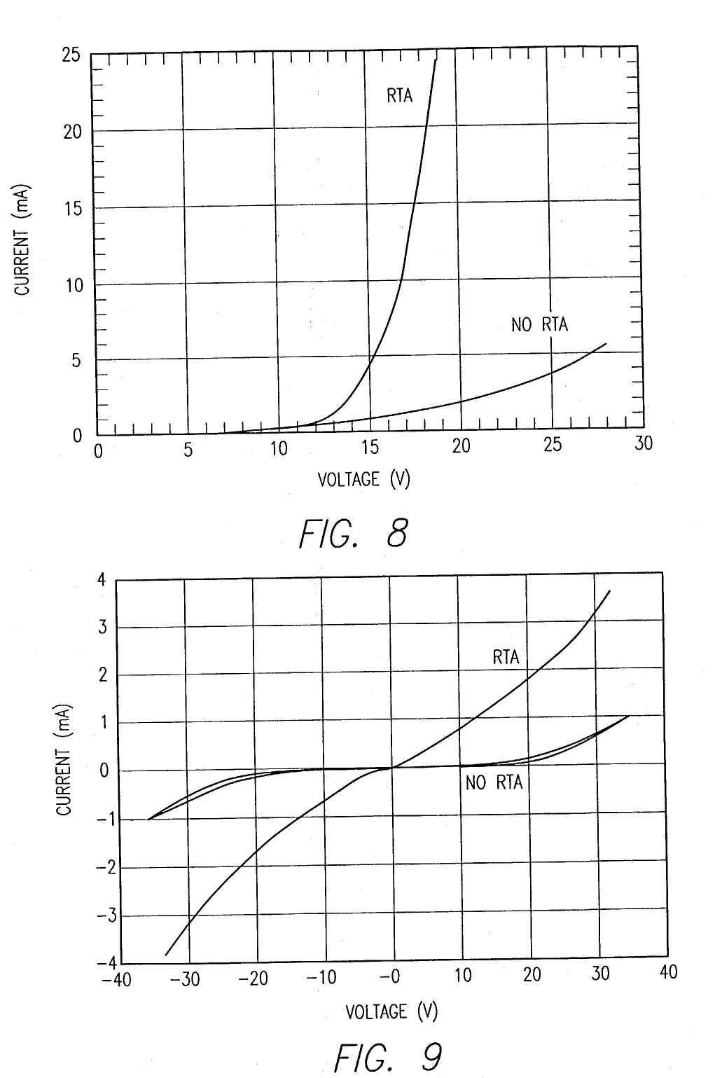

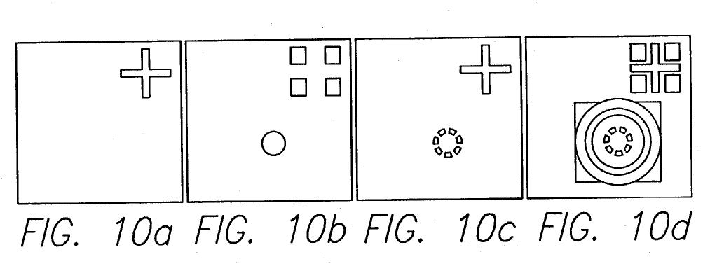

Implantation at doses of 10¹³ cm⁻² and higher resulted in open-circuit devices, indicating that the p-GaN was rendered insulating. Re-activating the material following the implant (prior to the contact deposition) did not change the device performance. However, while as-implanted areas on the wafer looked brownish in color, the re-activated sample was clear, implying that damage incurred by the crystal structure during implantation could be healed. At a dose of 10¹² ions/cm², the p-doped GaN was left sufficiently conductive for devices to operate, albeit with a turn-on voltage of approximately 30 V. Re-activated devices began conducting after only 2-3 volts of bias. FIG. 8 shows the CW current-voltage (I-V) characteristics for a 20 μm diameter aperture device, implanted with 10¹² cm⁻² Al at 180 keV, with a Pd/Au ring p-contact of 24 μm inner diameter, whereas FIG. 9 shows current-voltage (I-V). characteristics taken from p-p Transmission Line Method (TLM) pads before and after re-activation (RTA) for the 10¹² cm⁻² dose sample.

Regrowth:

Since one of the purposes of ion implantation is to confine current by surrounding a conducting path with resistive material, a dosage of 10¹² cm⁻² was considered to be fairly low. Moreover, higher doses resulted in damage to the p-contact layer. Regrowth of undamaged material after the implantation step can provide for conduction, ohmic contacts, and a repairing anneal. Given that the material is still resistive after a re-activation anneal (at 950° C.), it is reasonable to expect that regrowth, which is carried out at around 1100° C., should not nullify the implant.

Opto-electronic devices, such as LEDs, were fabricated, as shown in FIG. 10, with a larger difference (5 μm) between the diameters of the metal ring and the implant aperture so that current confinement could be observed using an optical microscope. In order to ensure that the unimplanted aperture, invisible after regrowth, would be aligned to the center of the contact-ring, a 1000 Å Ta₂O₅ alignment pattern was deposited prior to regrowth. The implant-masking layer, 200 Å Ti and 2000 Å Au, was then aligned to the Ta₂O₅ marks, and the wafers were then implantated. Ta₂O₅ is an ideal dielectric for regrowth, since it withstands the high reactor temperatures, is not etched by buffered hydrofluoric acid (BHF), and does not autodope the p-GaN in the same manner as SiO₂.

Specifically, with regards to FIG. 10, shown therein is a process schematic for implantation and regrowth. The process steps include: (a) a Ta₂O₅ alignment pattern being deposited on the p-GaN layer; (b) a Ti/Au mask being aligned to the Ta₂O₅ and the sample is implanted, leaving a damage free aperture; (c) the Ti/Au mask is stripped using BHF etchant, leaving the Ta₂O₅ untouched, and an additional p-GaN is grown (the implant position becomes invisible, although the Ta₂O₅ mask is left clear of GaN); (d) aligning to the Ta₂O₅, mesas are formed and the p-contact is deposited 5 μm from the unimplanted aperture so that confinement can be observed.

Three samples were implanted, again, using 180 keV aluminum, with doses of 10¹³, 10¹⁴, and 10¹⁵ cm⁻². The Ti/Au mask was then stripped using Au etchant and BHF, and 1230 Å of p-doped GaN were grown on each sample. The dielectric patterns were relatively free of overgrowth, and were clearly visible for alignment of the mesa and contact patterns.

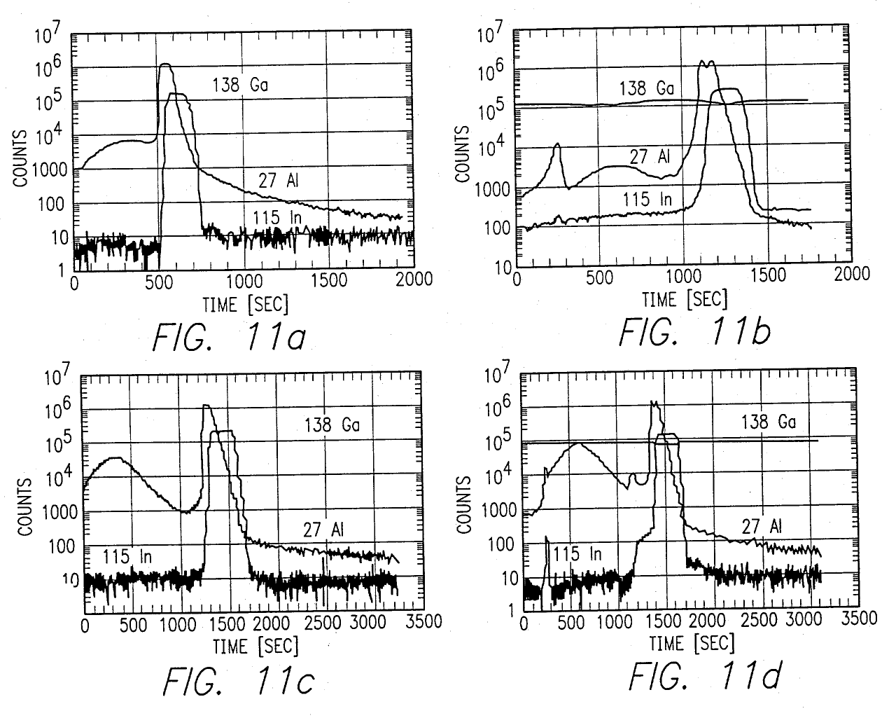

Secondary ion mass spectroscopy (SIMS) was performed on similar samples to ascertain what the implant profile would be before and after regrowth. As seen in FIG. 11 the implant is shown to clearly penetrate into the active region thereby indicating that the straggle is longer than predicted by SRIM, and that a lower energy, potentially, could be used in future experiments. Specifically, with regards to FIG. 11, shown therein are the SIMS analysis of the implanted samples. Notably, FIG. 11(a) and (b) shows the results from implantation with 10¹⁴ cm⁻² aluminum at 180 keV, before and after regrowth, respectively. FIGS. 11(c), (d) shows the results from implantation with 10¹⁵ cm⁻² aluminum at 180 keV, before and after regrowth, respectively.

Following regrowth, a large aluminum spike is visible at the interface between the new and old p-GaN layers which was most likely an artificial enhancement of the SIMS signal by impurities or disorder at that regrowth interface.

Device Results:

The p-GaN regrowth for the 10¹³ cm⁻² dose sample was fairly low, and as such, the p-p TLM characteristics indicated a 10 V Schottky barrier in both bias directions. Devices from the other two wafers exhibited positive behavior such as electro-luminescence with the light clearly confined to the unimplanted aperture. FIG. 5 shows an optical micrograph of confined light emission in one of the regrown semiconductor device. The metal ring has an inner diameter of 15 μm, while the unimplanted area in the center has a diameter of 5 μm. The left photo shows the unbiased device, while the right photo clearly shows confinement within an aperture away from the contact. Thus, as can be clearly seen, light is emitted in the center, and not from underneath the ring contact.

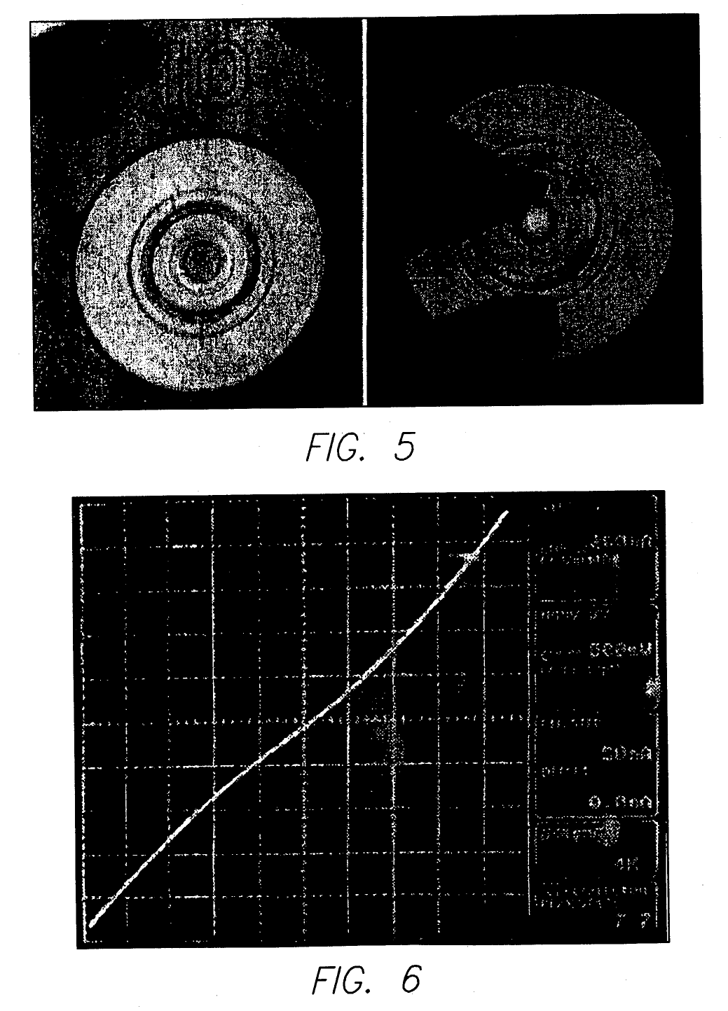

FIG. 6 shows the p-p TLM I-V characteristics for the samples implanted with 10¹⁴ cm⁻² aluminum at 180 keV after regrowth of 1200 Å p-GaN, where Pd/Au was used as the p-contact. While a 4 V barrier exists in the higher dosage sample, the 10¹⁴ cm⁻² devices clearly have ohmic contacts. Representative I-V characteristics for these devices indicate a turn-on voltage around 11 V for the 10¹⁴ cm⁻² sample. Occasionally, an initial forward bias of up to 30 V was needed to break through a barrier most likely caused by the regrowth interface. With improved treatment, prior to regrowth, this barrier could be eliminated.

Light versus current (L-I) measurements on these devices indicated a favorable behavior and a higher current carrying capacity was achievable as a result of using two metal contacts.

An example of the invention is given below. It should be noted however, that this is only one method of practicing this invention. Alternate energies, doses, and species may be used within the scope of the claims, as well as mask types and geometrical dimensions and specifications.

### EXAMPLE

An LED structure with a 5000 Å thick p-doped GaN top layer was implanted for current confinement.

(1) Using TRIM, for an aluminum species, an energy of 180 keV was chosen to disorder at least 1600 Å of material (straggle and channeling in GaN will most likely increase this depth). The chosen dosage was 10¹⁴ cm⁻².

(2) The sample was patterned with an alignment pattern made out of dielectric material (to survive the regrowth process; alternately, a refractory metal could be used).

(3) A 200 Å/2000 Å Ti/Au mask was deposited using a liftoff process to serve as the implant mask. The titanium served as a metal-to-semiconductor sticking layer, and the gold thickness was chosen to exceed the penetration depth of 180 keV Al into Au calculated by TRIM simulations.

(4) The sample was then implanted at the above conditions.

(5) The metal mask was etched away (Au etchant and BHF).

(6) A 1200 Å p-doped (Mg) GaN layer was regrown at 1010° C. by metalorganic chemical vapor deposition (MOCVD).

(7) Mesas and contacts were then aligned to the alignment marks deposited in (2). The geometry was such that the p-contact was a circular ring surrounding the unimplanted aperture, with approximately 5 μm between the aperture and the metal, so that the confinement could be observed under an optical microscope.

For the implant masks, alternate metals such as Nickel or Platinum could be used. It is to be noted that mostly any material could be used as an implant mask as long as, (i) it was capable of stopping implantation (based on SRIM), and (ii) it could be removed afterwards so that regrowth would be achieved.

The attached description of exemplary and anticipated embodiments of the invention have been presented for the purposes of illustration and description. They are not intended to be exhaustive or to limit the invention to the precise forms disclosed. Many modifications and variations are possible in light of the teachings herein. For example, there could be multiple, physically separate, implant regions in the semiconductor device. Furthermore, as mentioned, the semiconductor device could be a VCSEL. In this case, as is well known in the art,. the process would further include removing a portion of a substrate in the VCSEL using etching (e.g., photo-electro-chemical (PEC) etching), and depositing at least one mirror on the VCSEL. Moreover, the region to be implanted (e.g., the GaN region) could be grown on the substrate through a lateral epitaxial overgrowth (LEO) process (lateral epitaxial overgrowth is a technique in which the crystal quality is improved, thus reducing the number of non-radiative recombination sites which reduce the efficiency of the semiconductor device).

Alternatively, the ion implantation process could be used in an RCLED (as described in “Ion implantation for current confinement in InGaN-based RCLEDs”, T. Margalith, P. M Pattison, P. R. Tavernier, D. R. Clarke, S. Nakamura, S. P. DenBaars, and L. A. Coldren, Proc. 4^{th} Intl. Symp. on Blue Lasers and Light Emitting Diodes, March 2002.), LED, or other vertical opto-eletronic devices as indicated below.

Vertical optoelectronics (preferably emitters) include light emitting diodes (LEDs), resonant cavity light emitting diodes (RCLEDs), and vertical cavity surface emitting lasers (VCSELs). An LED is basically and active region consisting of (usually) one or more quantum wells, sandwiched between n- and p-doped material. An RCLED takes the standard LED and places it between 2 mirrors of intermediate reflectivity (actually, the common case is to have one very reflective mirror (80-90%) and one medium mirror (R˜50%)), to create a resonant cavity with improved spectral characteristics. A VCSEL is an RCLED taken to the extreme case of having 2 high reflectivity mirrors around the active region, so that gain can exceed the optical loss (transmission through the mirrors) and lasing can be achieved. All three structures can thus benefit from confining current to a region away from underneath the contacts. Especially, for VCSELs, it is likely that any absorption by overlying contacts would prevent lasing hence current confinement through ion implantation would be particularly beneficial.

The primary concern when designing RCLED and VCSEL cavities is the choice of reflectors. Mirrors can be either epitaxial (grown by MOCVD), dielectric, or metallic. One could also use the natural reflection off an air interface. At-present, epitaxial mirrors in the Al/Ga/In/B—N system are difficult to grow—although efforts are underway to achieve these at the University of California (Santa Barbara), and Sandia NL has shown that it is possible to achieve 99% reflectivity. Thus, RCLED and VCSEL efforts at UCSB have focused on deposited mirrors (not grown). To successfully incorporate these, it is useful (although not strictly necessary for an RCLED) to remove the substrate (which is generally made of sapphire). One of the techniques that can be used to do so is photo-electro-chemical etching (PECE) of a sacrificial layer. When the structure is grown, a sacrificial layer of low-bandgap material is incorporated in the layers below the device. Using a wavelength of light that excites carriers in that sacrificial layer only, along with a solution of KOH (for example) allows for selective etching. Once the layer is etched away, the original substrate is detached, leaving only the device layers.

An interesting related application involves using PECE to etch multiple sacrificial layers inserted between unetched layers (InGaN S.L./GaN) in an alternating stack. PECE then results in air/GaN stacks. These stacks could be tailored to act as mirrors if each layer (air/GaN) is a quarter-wavelength thick, and using the GaN-air index contrast.

Neither the choice of mirrors nor the decision to remove the substrate negates the use of ion implantation to improve the light output of the device. In fact, there are numerous other methods of designing an RCLED or VCSEL cavity that could separately use ion-implantation.

While the specification describes particular embodiments of the present invention, those of ordinary skill can devise variations of the present invention without departing from the inventive concept.

We claim:

1. A method for confining current in a semiconductor structure, the method comprising:
selectively disordering a doped nitride based material in a semiconductor structure;
wherein the selective disordering substantially increases the resistance of the material, adjacent a contact, to a current thereby confining the current to a region of substantially low resistance in the doped nitride based material.

2. The method according to claim 1, wherein the selective disordering reduces the emission of light below the contact.

3. The method according to claim 1, wherein the selective disordering of the doped nitride based material is performed by ion implantation.

4. The method according to claim 3, wherein the implantation is done by a species of ions.

5. The method according to claim 4, wherein the weight of the species of ions is larger than the weight of helium ions.

6. The method according to claim 5, wherein the species of ions include aluminum ions.

7. The method according to claim 1, wherein the nitride based material further includes at least one of Gallium (Ga), Indium (In), Aluminum (Al), or Boron (B).

8. The method according to claim 1, wherein the nitride based material is p-doped GaN.

9. A method for confining current in an vertical opto-electronic device, the method comprising:
selectively disordering a doped nitride based material in the vertical opto-electronic device;
wherein the selective disordering substantially increases the resistance of the material, below a contact, to a current thereby confining the current to a region of substantially low resistance in the doped nitride based material.

10. The method according to claim 9, wherein the vertical opto-electronic device is at least one of a VCSEL, LED, and RCLED.

11. The method according to claim 9, wherein the selective disordering reduces the emission of light below the contact.

12. The method according to claim 9, wherein the selective disordering of the doped nitride based material is performed by ion implantation.

13. The method according to claim 12, wherein the implantation is done by a species of ions.

14. The method according to claim 14, wherein the species of ions include aluminum ions.

15. The method according to claim 9, wherein the nitride based material further includes at least one of Gallium (Ga), Indium (In), Aluminum (Al), or Boron (B).

16. The method according to claim 9, wherein the nitride based material is p-doped GaN.

17. A method for reducing the emission of light adjacent a contact of a semiconductor structure, the method comprising:
selectively disordering a doped nitride based material in a semiconductor structure;
wherein the selective disordering substantially increases the resistance of the material, adjacent a contact, to a current thereby reducing the emission of light at the contact.

18. The method according to claim 17, wherein the current is confined to a region of substantially low resistance in the doped nitride based material.

19. The method according to claim 17, wherein the selective disordering of the doped nitride based material is performed by ion implantation.

20. The method according to claim 19, wherein the implantation is done by a species of ions.

21. The method according to claim 20, wherein the weight of the species of ions is larger than the weight of helium ions.

22. The method according to claim 21, wherein the species of ions include aluminum ions.

23. The method according to claim 17, further comprising the step of growing a layer of a substantially conductive doped material on the semiconductor structure.

24. The method according to claim 19, wherein the ion implantation provides means for index guiding of light.

25. The method according to claim 23, further comprising the step of forming contacts for applying the current to the semiconductor structure.

26. The method according to claim 17, wherein the nitride based material further includes at least one of Gallium (Ga), Indium (In), Aluminum (Al), or Boron (B).

27. The method according to claim 17, wherein the nitride based material is p-doped GaN.

28. The method according to claim 17, further comprising the step of masking the semiconductor structure using a masking material.

29. The method according to claim 28, wherein the choice of the masking material is based on at least one of a density and thickness of said masking material to obtain a predetermined amount of implantation stopping distance.

30. The method according to claim 28, wherein the masking material is at least one of Titanium (Ti) or Gold (Au).

31. A method of using ion implantation for providing index wave-guiding of emitted light in a semiconductor structure, the method comprising:
selectively disordering a doped nitride based material in a semiconductor structure using ion implantation;
wherein the ion implantation reduces the refractive index of the disordered and doped nitride based material thereby providing index wave-guiding of emitted light in the semiconductor structure.

32. The method according to claim 31, wherein the disordered and doped nitride based material having lower refractive index surrounds the nitride based material having a higher refractive index.

33. The method according to claim 31, wherein the index wave-guiding of emitted light is due to the lower refractive index material surrounding the higher refractive index material which leads to light guiding along the high refractive index material.

34. The method according to claim 31, wherein the nitride based material further includes at least one of Ga, In, Al, or B.

35. The method according to claim 31, wherein the implantation is done by a species of ions.

36. The method according to claim 35, wherein the weight of the species of ions is larger than the weight of helium ions.

37. The method according to claim 35, wherein the species of ions include Al ions.

38. A method for improving the light output in a vertical cavity surface emitting laser (VCSEL), the method comprising:
removing a portion of a substrate in the VCSEL using etching; and
selectively disordering a doped nitride based material in the VCSEL;
wherein the selective disordering substantially increases the resistance of the material, adjacent at least one contact of the VCSEL, to a current thereby improving the light output in the VCSEL.

39. The method according to claim 38, wherein the current is confined to a region of substantially low resistance in the doped nitride based material.

40. The method according to claim 38, wherein the selective disordering of the doped nitride based material is performed by ion implantation.

41. The method according to claim 40, wherein the implantation is done by a species of ions.

42. The method according to claim 41, wherein the species of ions include aluminum ions.

43. The method according to claim 41, wherein the nitride based material further includes at least one of Gallium (Ga), Indium (In), Aluminum (Al), or Boron (B).

44. The method according to claim 38, wherein the nitride based material is p-doped GaN.

45. The method according to claim 38, further including the step of depositing at least one mirror on the VCSEL.

46. The method according to claim 38, wherein the etching is performed by a photo-electro-chemical (PEC) etching process.

47. A method for improving the light output in a vertical cavity surface emitting laser (VCSEL), the method comprising:
growing a nitride based material on a substrate through lateral epitaxial overgrowth (LEO) process in the VCSEL; and
selectively disordering a p-doped nitride based material in the VCSEL;
wherein the selective disordering substantially increases the resistance of the p-doped material, adjacent at least one contact of the VCSEL, to a current thereby improving the light output in the VCSEL.

48. A semiconductor structure for confining a current, the structure comprising:
a selectively disordered and doped nitride based material;
wherein the selectively disordered material has a substantially higher resistance, adjacent a contact, to a current thereby confining the current to a region of substantially low resistance in the doped nitride based material.

49. The semiconductor structure according to claim 48, wherein the selective disordering of the doped nitride based material is performed by ion implantation.

50. The semiconductor structure according to claim 48, wherein the implantation is done by a species of ions.

51. The semiconductor structure according to claim 49, wherein the species of ions include aluminum ions.

52. The semiconductor structure according to claim 48, further including a layer of a substantially conductive doped material.

53. The semiconductor structure according to claim 48, wherein the ion implantation provides means for index guiding of light.

54. The semiconductor structure according to claim 48, wherein the nitride based material further includes at least one of Gallium (Ga), Indium (In), Aluminum (Al), or Boron (B).

55. The semiconductor structure according to claim 48, wherein the nitride based material is p-doped GaN.
